(19) United States
(12) Patent Application Publication
(10) Pub. No.: US 2013/0329384 A1
(43) Pub. Date: Dec. 12, 2013

(54) Transmission Control Device and Electronic Circuit Device

(71) Applicants: Kiyotaka Kanno, Hitachinaka (JP); Yasunori Odakura, Hitachinaka (JP)

(72) Inventors: Kiyotaka Kanno, Hitachinaka (JP); Yasunori Odakura, Hitachinaka (JP)

(73) Assignee: HITACHI AUTOMOTIVE SYSTEMS, LTD., Hitachinaka-shi, Ibaraki (JP)

(21) Appl. No.: 13/985,235

(22) PCT Filed: Feb. 21, 2012
(86) PCT No.: PCT/JP2012/054162

§ 371 Date: Aug. 13, 2013

(30) Foreign Application Priority Data
Mar. 1, 2011 (JP) 2011-043464

(51) Int. Cl. H05K 1/02

(52) U.S. Cl. CPC H05K 1/0212
USPC 361/752

(57) ABSTRACT

There is a problem that heat dissipation of heat generated by a bear chip deteriorates. Further, if parts are buried in sealing resin while a heatsink is exposed to improve heat dissipation, there are problems of peeling and occurrence of cracking.

An electronic circuit device in which an electronic circuit assembly which controls a transmission and a drive for an automobile, a base which fixes the electronic circuit assembly and lead terminals which are electrically connected with the electronic circuit assembly are sealed by mold resin, adopts a heat dissipation structure which has: an opening portion which penetrates a circuit substrate and the base below a heater circuit element (bear chip), and in which both surfaces of a heater element and sealing resin are thermally coupled.

### TECHNICAL FIELD

The present invention relates to an automobile transmission control device, and is suitable to, for example, a control valve which controls an automatic transmission and an electronic circuit device which controls a control target part of the control valve.

### BACKGROUND ART

FIG. 11 illustrates an electronic circuit device 1 in which an electronic circuit assembly which controls a transmission and a drive for an automobile, a base which fixes the electronic circuit assembly and lead terminals which are electrically connected with the electronic circuit assembly are sealed by mold resin. FIGS. 11(B) and (C) are partial cross-sectional views along a I-I line and a II-II line of FIG. 11(A). To a base 2 which has a flange portion 2a, an electronic circuit assembly 5 which is formed with a circuit substrate 8 on which a circuit element 6 and a bear chip 7 are mounted is adhered and fixed by an adhesive 10 such as epoxy. Lead terminals 3 are arranged to meet bonding pat portions 12 of the electronic circuit assembly 5. As to the electronic circuit assembly 5 and the lead terminals 3, the bonding pat portions 12 of the electronic circuit assembly 5 and bonding pat portions 3a of the lead terminals 3 are electrically connected through aluminum thin wires 11 according to a wire bonding method. The electronic circuit assembly 5 is adhered and fixed to a top surface of the base 2 by the adhesive 10, the electronic circuit assembly 5 and the lead terminals 3 are connected by the aluminum thin wires 11 and then these parts, the circuit element 6, the bear chip 7, the circuit substrate 8, the base 2 and the lead terminals 3 are collectively buried in sealing resin 4 except part of the lead terminals 3 and part of the flange portion 2a of the base 2. The sealing resin 4 is made by transfer mold forming, and thermosetting resin such as epoxy resin is generally used as sealing resin to let the resin flow and solidify in a mold. The bear chip 7 is jointed to the circuit substrate 8 by a solder and a silver paste material, and is electrically connected with the circuit substrate 8 by Au thin wires 9. For the circuit substrate 8, a ceramic substrate of great thermal conductivity is used. Heat produced by the bear chip 7 is dissipated from the sealing resin 4 which is closely attached to the bear chip 7, and is conducted through the circuit substrate 8 on which the bear chip 7 is mounted, a substrate adhering portion 2b and the base 2 and is dissipated to a mating part through the flange portion 2a.

### CITATION LIST

### Patent Literature

PTL 1: Japanese Patent Application Laid-Open No. 2002-261197

PTL 2: Japanese Patent Application Laid-Open No. 2007-43196

### SUMMARY OF INVENTION

### Technical Problem

However, a structure of a conventional electronic circuit device uses a ceramic substrate of great thermal conductivity for a circuit substrate to obtain high heat dissipation, and therefore is costly. Although a low-cost structure is made by a method of adopting a glass epoxy substrate for a circuit substrate, the glass epoxy substrate has less thermal conductivity than a ceramic substrate. Heat produced by a bear chip is dissipated from sealing resin which is closely attached to the bear chip, and is conducted through a circuit substrate on which the bear chip is mounted, a substrate adhering portion and a base and is dissipated to a mating part through a flange portion which is formed integrally with the base, if a glass epoxy substrate of poor thermal conductivity is used for the circuit substrate, there is a problem that heat dissipation of heat produced by the bear chip worsens. Further, if parts are buried in sealing resin while a heatsink is exposed to improve heat dissipation, there are problems of peeling and occurrence of cracking. Furthermore, the number of parts increases, thereby deteriorating productivity and increasing cost.

### Solution to Problem

The above object is achieved by the invention recited in the claims.

For example, an electronic circuit device in which an electronic circuit assembly which controls a transmission and a drive for an automobile, a base which fixes the electronic circuit assembly and lead terminals which are electrically connected with the electronic circuit assembly are sealed by mold resin, has an opening portion which penetrates a circuit substrate and the base below a heater circuit element (bear chip), and both surfaces of a heater element and sealing resin are thermally coupled.

### Advantageous Effects of Invention

According to a first effect of the present invention, the electronic circuit device has an opening portion which penetrates a circuit substrate and the base below a heater circuit element (bear chip), and both surfaces of a heater element and sealing resin are thermally coupled, so that heat produced by a bear chip is conducted to the base through sealing resin of great thermal conductivity without being conducted through a glass epoxy substrate of poor thermal conductivity, and is dissipated to a mating part through a flange portion. Further, it is possible to improve heat dissipation at low cost by using sealing resin as a thermally conducting material instead of a heatsink.

According to a second effect, the electronic circuit device has a route opening portion which allows sealing resin to be filled in the circuit substrate and a base, so that it is possible to improve fluidity of sealing resin to the opening portion which penetrates the circuit substrate chip and the base below the bear chip upon transfer mold forming, reduce generation of a void below the bear chip and efficiently and thermally couple the sealing resin to the both surfaces of the bear chip.

By this means, it is possible to improve heat dissipation and simplify a heat dissipation structure of the electronic circuit device.

### BRIEF DESCRIPTION OF DRAWINGS

FIG. 1 is a heat dissipation structure of an electronic circuit device according to a first embodiment.

FIG. 2 is a detail cross-sectional view of a heat dissipation structure according to a second embodiment.

FIG. 3 is a detail cross-sectional view of a heat dissipation structure according to a third embodiment.

FIG. 4 is a detail view of an oblique direction route opening of a circuit substrate.

FIG. 5 is a detail view of a combination of the route opening and a straight direction route opening of the circuit substrate.

FIG. 6 is a detail view of a combination of the oblique direction route opening and the straight direction route opening of the circuit substrate.

FIG. 7 is a cross-sectional view of a groove-shaped route opening of the circuit substrate.

FIG. 8 is a heat dissipation structure of an electronic circuit device according to a fourth embodiment.

FIG. 9 is a detail cross-sectional view of the heat dissipation structure according to the fourth embodiment.

FIG. 10 is a cross-sectional view of a groove-shaped route opening of a circuit substrate according to the fourth embodiment.

FIG. 11 illustrates a heat dissipation structure of a conventional electronic circuit device.

### DESCRIPTION OF EMBODIMENTS

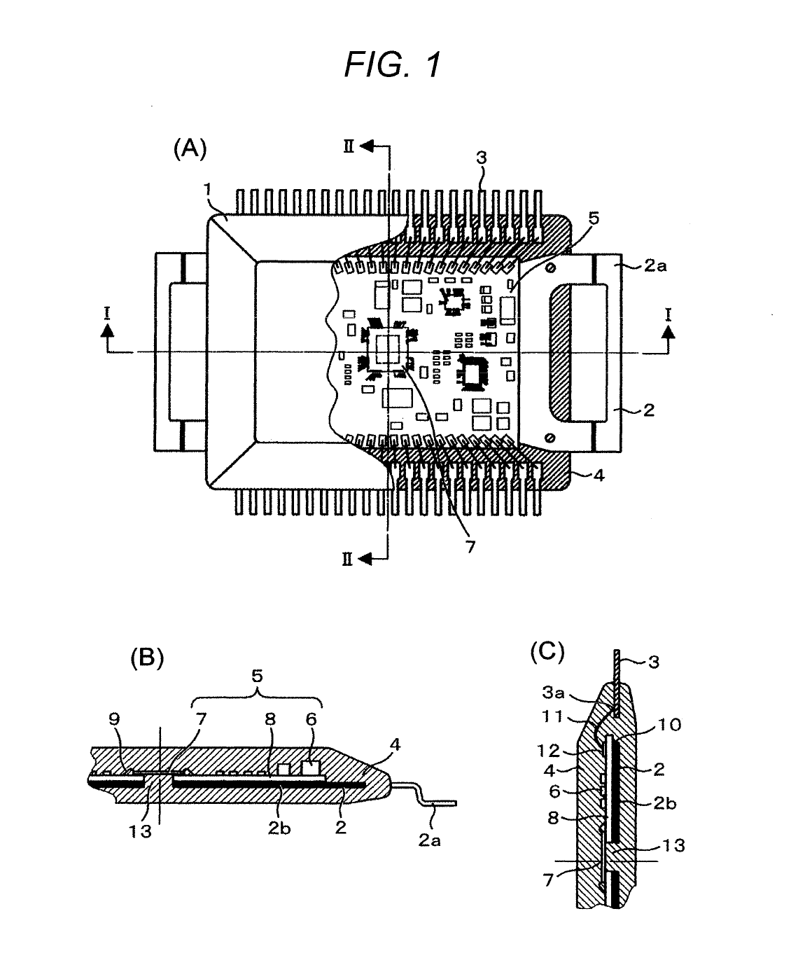

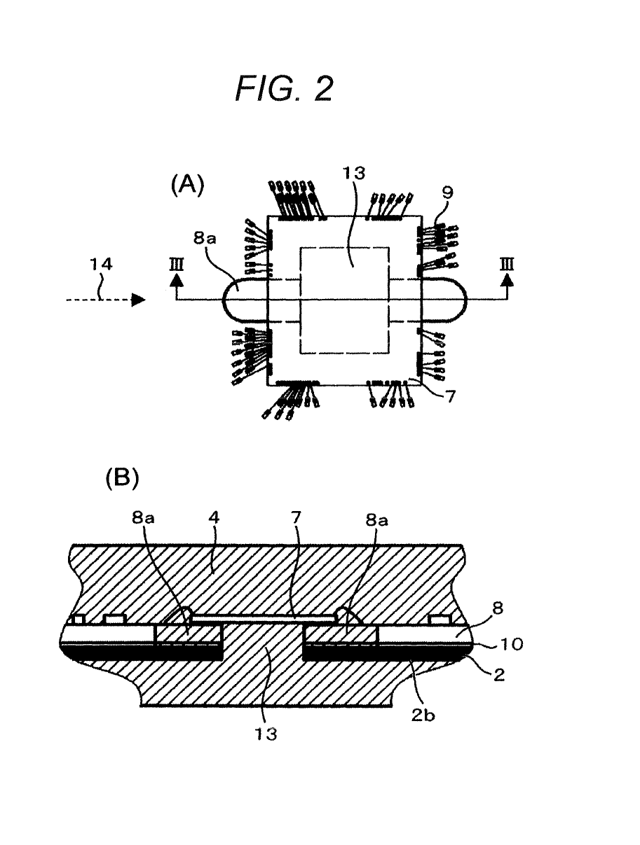

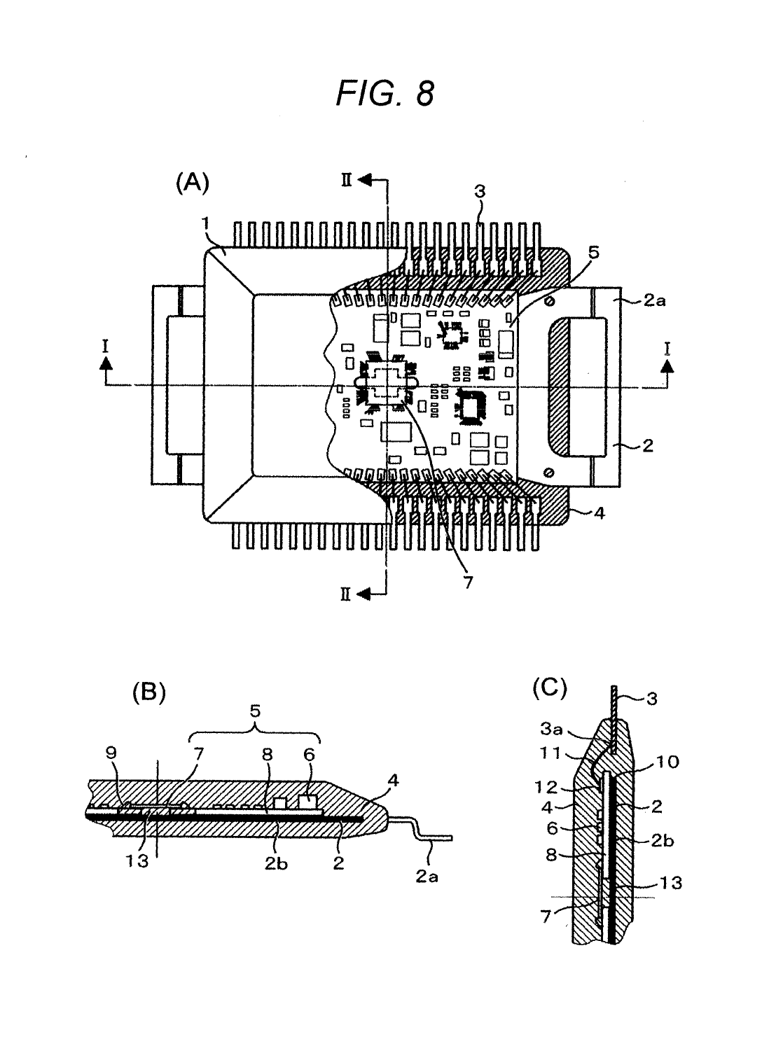

Embodiments of the present invention will be described below with reference to FIG. 1 to FIG. 10. FIGS. 1 and 8 illustrate an electronic circuit device 1 in which an electronic circuit assembly which controls a transmission and a drive for an automobile, a base which fixes the electronic circuit assembly and lead terminals which are electrically connected with the electronic circuit assembly are sealed by mold resin. FIGS. 2, 3 and 9 are detail views of a bear chip 7 portion. The cross-sectional view is a partial cross-sectional view along a III-III line. FIGS. 4 to 6 are detail views of route opening portions 8a and 8b which are provided in and penetrate a circuit substrate 8, and FIGS. 7 and 10 are detail views of a groove-shaped route opening portion 8c.

### First Embodiment

FIG. 1 illustrates a first embodiment of the present invention. FIGS. 1(B) and (C) are partial cross-sectional views along a I-I line and a II-II line of FIG. 1(A).

In the present embodiment, to a base 2 which has a flange portion 2a, an electronic circuit assembly 5 which is formed with a circuit substrate 8 on which a circuit element 6 and a bear chip 7 are mounted is adhered and fixed by an adhesive 10 such as epoxy. Lead terminals 3 are arranged to meet bonding pat portions 12 of the electronic circuit assembly 5. As to the electronic circuit assembly 5 and the lead terminals 3, the bonding pat portions 12 of the electronic circuit assembly 5 and bonding pat portions 3a of the lead terminals 3 are electrically connected through aluminum thin wires 11 according to a wire bonding method. The electronic circuit assembly 5 is adhered and fixed to a top surface of the base 2 by the adhesive 10, the electronic circuit assembly 5 and the lead terminals 3 are connected by the aluminum thin wires 11 and then these parts, the circuit element 6, the bear chip 7, the circuit substrate 8, the base 2 and the lead terminals 3 are collectively buried in sealing resin 4 except part of the lead terminals 3 and part of the flange portion 2a of the base 2. The sealing resin 4 is made by transfer mold forming, and thermosetting resin such as epoxy resin is generally used as sealing resin to let the resin flow and solidify in a mold. The bear chip 7 is jointed to the circuit substrate 8 by a solder and a silver paste material, and is electrically connected with the circuit substrate 8 by Au thin wires 9. For the circuit substrate 8, a glass epoxy substrate is used. Below the bear chip 7, an opening portion 13 which penetrates the circuit substrate 8 and the base 2 are provided, and both surfaces of the bear chip 7 are closely attached to the sealing resin 4. Heat produced by the bear chip 7 is dissipated from the sealing resin 4 which are closely attached to the both surfaces of the bear chip 7. Further, heat is conducted through the base 2 which is closely attached to the sealing resin 4, and is dissipated to a mating part through the flange portion 2a.

### Second Example

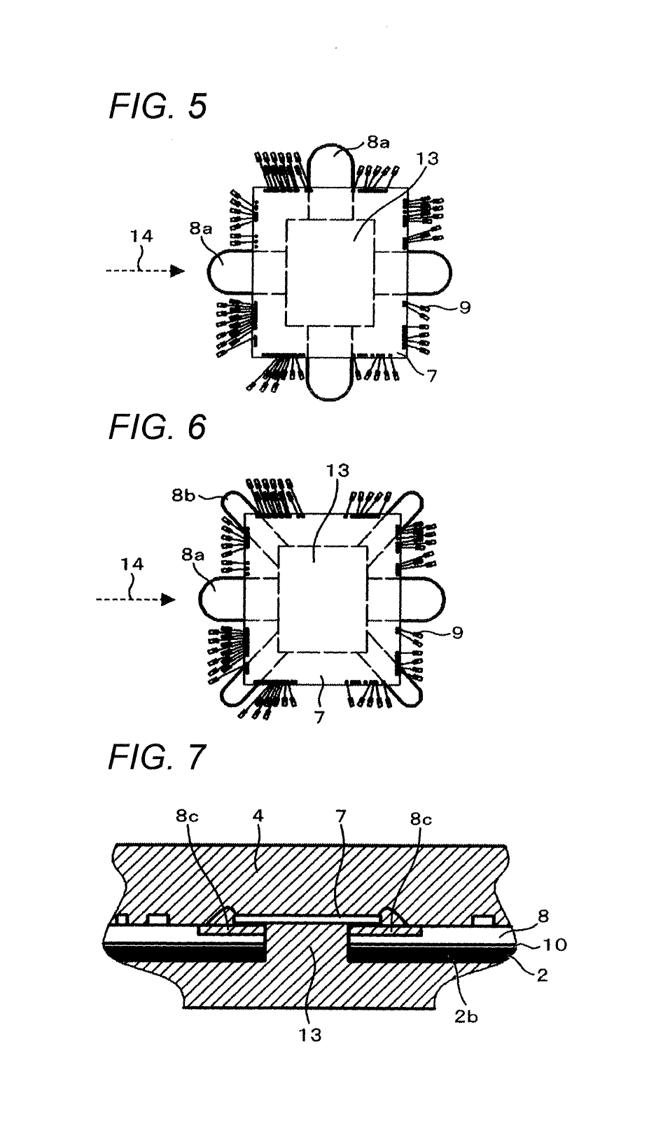

FIG. 2 illustrates a second embodiment of the present invention. FIG. 2(B) is a partial cross-sectional view along a III-III line of FIG. 2(A). To make it easy to fill sealing resin 4 in an opening portion 13 which penetrates a circuit substrate 8 and a base 2 compared to the first embodiment, the circuit substrate 8 has a route opening portion 8a which penetrates in a straight direction with respect to a resin flow direction 14 to improve fluidity of the sealing resin 4 to the opening portion 13 which penetrates the circuit substrate 8 and the base 2 below the bear chip 7 upon transfer mold forming, reduce generation of a void below the bear chip 7 and efficiently and thermally couple the sealing resin 4 to both surfaces of the bear chip 7. In this case, as illustrated in FIG. 4, a route opening portion may be a route opening portion 8b which penetrates in oblique directions with respect to the resin flow direction 14. Further, as illustrated in FIGS. 5 and 6, the route opening portion 8a which penetrates in the straight direction and the route opening portion 8b which penetrates in the oblique directions may be combined to further improve fluidity of resin. Furthermore, as illustrated in FIG. 7, the route opening portion of the circuit substrate 8 may be a groove-shaped route opening portion 8c.

### Third Embodiment

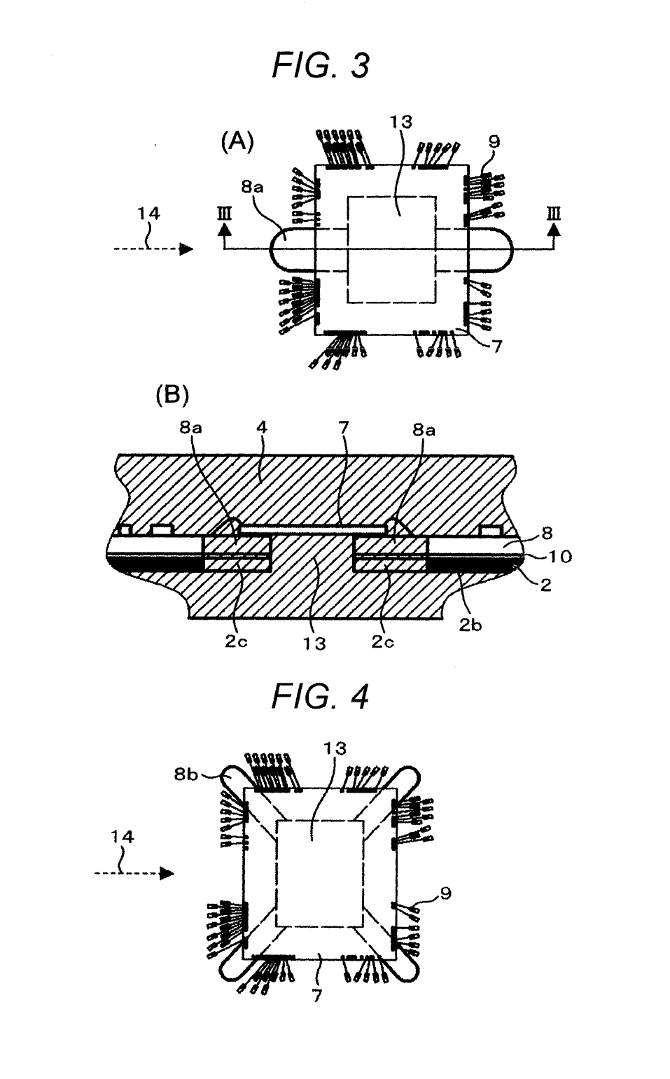

FIG. 3 illustrates a third embodiment of the present invention. FIG. 3(B) is a partial cross-sectional view along a III-III line of FIG. 3(A). To make it easy to fill sealing resin 4 in an opening portion 13 which penetrates a circuit substrate 8 and a base 2 compared to the first embodiment, the circuit substrate 8 and the base 2 have route opening portions 8a and 2c which penetrates in a straight direction with respect to a resin flow direction 14 to improve fluidity of the sealing resin 4 to the opening portion 13 which penetrates the circuit substrate 8 and the base 2 below the bear chip 7 upon transfer mold forming, reduce generation of a void below the bear chip 7 and efficiently and thermally couple the sealing resin 4 to both surfaces of the bear chip 7. In this case, as illustrated in FIG. 4, a route opening portion may be a route opening portion 8b which penetrates in oblique directions with respect to the resin flow direction 14. Further, as illustrated in FIGS. 5 and 6, the route opening portion 8a which penetrates in the straight direction and the route opening portion 8b which penetrates in the oblique directions may be combined to further improve fluidity of resin.

### Fourth Embodiment

FIG. 8 illustrates a fourth embodiment of the present invention. FIGS. 8(B) and (C) are partial cross-sectional views along a I-I line and a II-II line of FIG. 8(A).

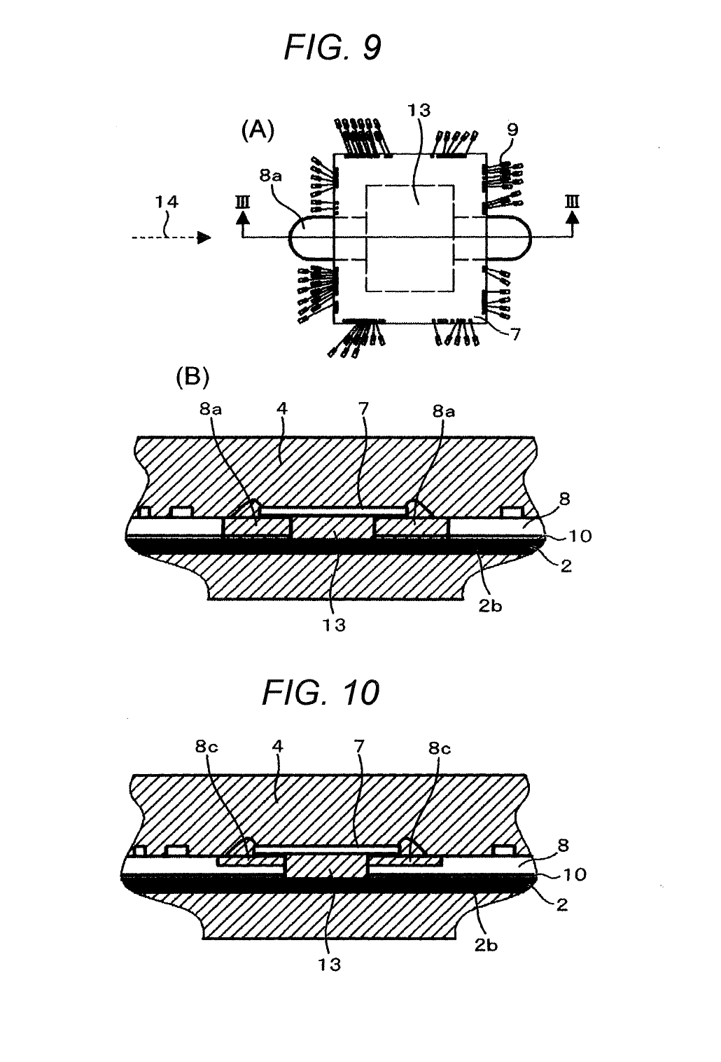

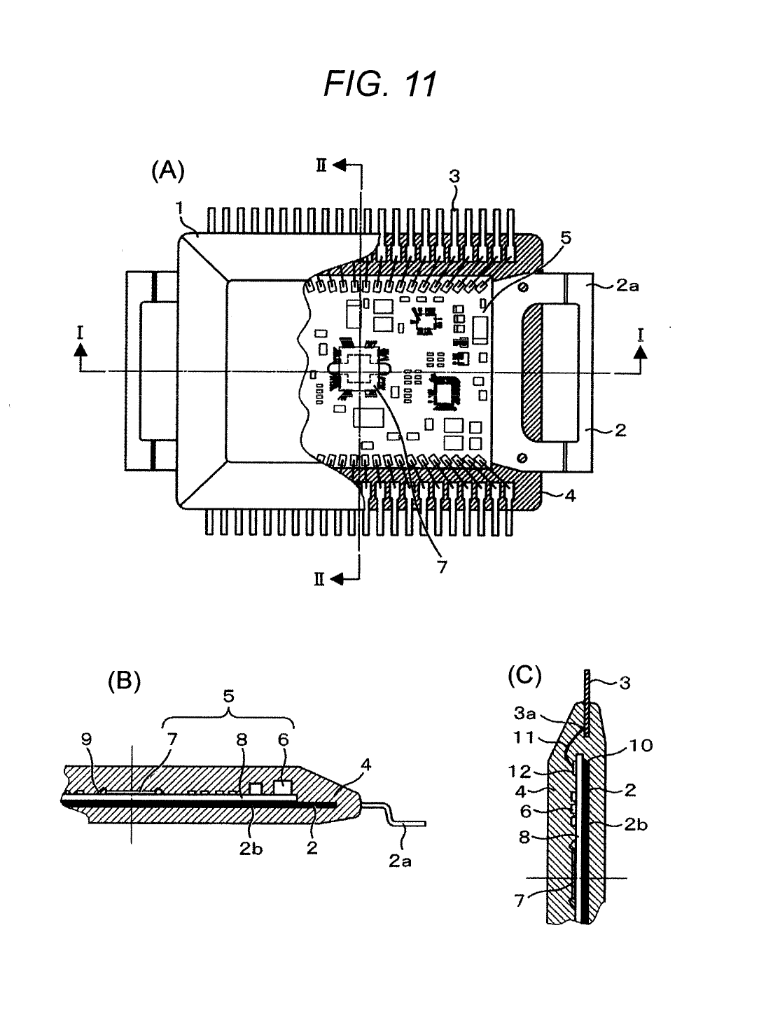

In the present embodiment, to a base 2 which has a flange portion 2b, an electronic circuit assembly 5 which is formed with a circuit substrate 8 on which a circuit element 6 and a bear chip 7 are mounted is adhered and fixed by an adhesive 10 such as epoxy. Lead terminals 3 are arranged to meet bonding pat portions 12 of the electronic circuit assembly 5. As to the electronic circuit assembly 5 and the lead terminals 3, the bonding pat portions 12 of the electronic circuit assembly 5 and bonding pat portions 3a of the lead terminals 3 are electrically connected through aluminum thin wires 11 according to a wire bonding method. The electronic circuit assembly 5 is adhered and fixed to a top surface of the base 2 by the adhesive 10, the electronic circuit assembly 5 and the lead terminals 3 are connected by the aluminum thin wires 11 and then these parts, the circuit element 6, the bear chip 7, the circuit substrate 8, the base 2 and the lead terminals 3 are collectively buried in sealing resin 4 except part of the lead terminals 3 and part of the flange portion 2a of the base 2. The sealing resin 4 is made by transfer mold forming, and thermosetting resin such as epoxy resin is generally used as sealing resin to let the resin flow and solidify in a mold. The bear chip 7 is jointed to the circuit substrate 8 by a solder and a silver paste material, and is electrically connected with the circuit substrate 8 by Au thin wires 9. For the circuit substrate 8, a glass epoxy substrate is used. Below the bear chip 7, an opening portion 13 which penetrates the circuit substrate 8 is provided, and both surfaces of the bear chip 7 are closely attached to the sealing resin 4. Heat produced by the bear chip 7 is dissipated from the sealing resin 4 which are closely attached to the both surfaces of the bear chip 7. Further, heat is conducted through the base 2 which is closely attached to the sealing resin 4, and is dissipated to a mating part through the flange portion 2a which is formed integrally with the base. As illustrated in FIG. 9, to make it easy to fill the sealing resin 4 in an opening portion 13 which penetrates the circuit substrate 8 and the base 2, the circuit substrate 8 has a route opening portion 8a which penetrates in a straight direction with respect to a resin flow direction 14 to improve fluidity of the sealing resin 4 to the opening portion 13 which penetrates the circuit substrate 8 and the base 2 below the bear chip 7 upon transfer mold forming, reduce generation of a void below the bear chip 7 and efficiently and thermally couple the sealing resin 4 to both surfaces of the bear chip 7. In this case, as illustrated in FIG. 4, a route opening portion may be a route opening portion 8b which penetrates in oblique directions with respect to the resin flow direction 14. In addition, FIG. 9(B) is a partial cross-sectional view along a I-I line of FIG. 9(A). Further, as illustrated in FIGS. 5 and 6, the route opening portion 8a which penetrates in the straight direction and the route opening portion 8b which penetrates in the oblique directions may be combined to further improve fluidity of resin. Furthermore, as illustrated in FIG. 7, the route opening portion of the circuit substrate 8 may be a groove-shaped route opening portion 8c.

### REFERENCE SIGNS LIST

1 electronic circuit device
2 base
2a flange portion
2b substrate adhering portion
2c penetrating opening portion
3 lead terminal
3a, 12 bonding pat portion
4 sealing resin
5 electronic circuit assembly
6 circuit element
7 bear chip
8 circuit substrate
8a penetrating route opening portion (straight direction)
8b penetrating route opening portion (oblique direction)
8c groove-shaped route opening portion
9 Au thin wire
10 adhesive
11 aluminum thin wire
13 opening portion below chip
14 flow direction of sealing resin

1. A transmission control device which comprises:
a control circuit which comprises a heater element provided on a circuit substrate and outputs a control signal to a transmission of an automobile; and
a base member which supports the circuit substrate, and
in which the circuit substrate and the base member are molded by resin, wherein
an opening portion is provided in the base member and the circuit substrate directly below the heater element, and
the resin directly contacts a top surface and a bottom surface of the heater element.

2. The transmission control device according to claim 1, wherein
a route which communicates with the opening portion is formed in the circuit substrate, and
the opening portion and the route are continuously filled with the resin.

3. The transmission control device according to claim 1, wherein
a flange portion which is to be attached to the transmission is formed in part of the base member, and
the flange portion is not molded by the resin.

4. The transmission control device according to claim 2,
wherein a plurality of routes is provided radially from the opening portion.

5. An electronic circuit device in which an electronic circuit assembly which controls a transmission and a drive for an automobile, a base which fixes the electronic circuit assembly and lead terminals which are electrically connected with the electronic circuit assembly are sealed by mold resin, the electronic circuit device comprising:
an opening portion which penetrates a circuit substrate and a base below a bear chip which is a heater element,
wherein both surfaces of a heater element and sealing resin are thermally coupled.

6. The electronic circuit device according to claim 5,
further comprising a route opening portion which allows sealing resin to be filled in the circuit substrate, wherein both surfaces of a heater element and sealing resin are thermally coupled, and the sealing resin and the base are thermally coupled.

7. The electronic circuit device according to claim 5,
further comprising a route opening portion which allows sealing resin to be filled in the circuit substrate and the base, wherein both surfaces of a heater element and sealing resin are thermally coupled.

8. An electronic circuit device in which an electronic circuit assembly which controls a transmission and a drive for an automobile, a base which fixes the electronic circuit assembly and lead terminals which are electrically connected with the electronic circuit assembly are sealed by mold resin, the electronic circuit device comprising:
an opening portion of a circuit substrate below a bear chip which is a heater element; and
a route opening portion which allows sealing resin to be filled in the circuit substrate,
wherein both surfaces of a heater element and sealing resin are thermally coupled, and the sealing resin and the base are thermally coupled.
